(19) United States
(12) Patent Application Publication
(10) Pub. No.: US 2024/0429877 A1
(43) Pub. Date: Dec. 26, 2024

(54) Power Amplifying Device

(71) Applicant: Yamaha Corporation, Hamamatsu-shi (JP)

(72) Inventor: Masao NORO, Hamamatsu-si (JP)

(21) Appl. No.: 18/826,783

(22) Filed: Sep. 6, 2024

Related U.S. Application Data
(63) Continuation of application No. PCT/JP2023/007605, filed on Mar. 1, 2023.

(30) Foreign Application Priority Data
Mar. 7, 2022 (JP) 2022-034162

(51) Int. Cl. H03F 3/21

(52) U.S. Cl. CPC H03F 3/21; H03F 2200/03

(57) ABSTRACT

A power amplifying device includes: an amplifier circuit configured to amplify an input sound signal and output an output sound signal to an acoustic transducer; and a current feedback circuit configured to negatively feed back a current flowing through the acoustic transducer to the amplifier circuit. The voltage feedback circuit includes a voltage feedback resistor and a compensation circuit connected in parallel. A compensation impedance connected in parallel with the acoustic transducer and an output resistor connected in series with the acoustic transducer are virtually generated by the voltage feedback circuit and the current feedback circuit. An impedance of a parallel circuit of the acoustic transducer and the compensation impedance is flat as compared with a frequency characteristic of an impedance of the acoustic transducer. The output resistor has a value greater than a resistance value of the acoustic transducer.

### CROSS-REFERENCE TO RELATED APPLICATIONS

This is a continuation of International Application No. PCT/JP2023/007605, filed on Mar. 1, 2023, which claims priority from Japanese Patent Application No. 2022-034162, filed on Mar. 7, 2022, the entire content of each of which is incorporated herein by reference.

### TECHNICAL FIELD

The present disclosure relates to a power amplifying device.

### BACKGROUND

JPS58-218208A discloses an amplifying device in which a circuit having a frequency characteristic opposite to an impedance of a speaker is connected in series with the speaker. According to the amplifying device, the speaker is driven with a relatively low impedance in the vicinity of a low-frequency resonance frequency, and is driven with a relatively high impedance in other frequency bands. The amplifying device in the related art has an advantage of being able to improve current magnetostriction of the speaker.

### SUMMARY

However, in the related-art technique, an input voltage of the speaker is affected by the circuit connected in series with the speaker. Therefore, a frequency characteristic of the input voltage of the speaker is not flat. Meanwhile, in the speaker, when the frequency characteristic of the input voltage is flat, a frequency characteristic of emitted sound is flat. Therefore, the amplifying device in the related art has a problem in that the frequency characteristic of the speaker cannot be made flat.

In view of the above circumstances, an object of one aspect of the present disclosure is to drive an acoustic transducer with a flat frequency characteristic while reducing current magnetostriction.

The present disclosure provides a power amplifying device configured to generate an output sound signal by power amplifying an input sound signal, the power amplifying device including: an amplifier circuit configured to amplify the input sound signal and output an amplified signal as the output sound signal to an acoustic transducer configured to convert the output sound signal into sound; a voltage feedback circuit configured to negatively feed back a voltage of the output sound signal to an input of the amplifier circuit; and a current feedback circuit configured to negatively feed back a current flowing through the acoustic transducer to the input of the amplifier circuit, in which: the voltage feedback circuit includes a voltage feedback resistor and a compensation circuit connected in parallel with the voltage feedback resistor; a compensation impedance connected in parallel with the acoustic transducer is virtually generated by the voltage feedback circuit and the current feedback circuit, and an impedance of a parallel circuit in which the acoustic transducer and the compensation impedance are connected in parallel is flat as compared with a frequency characteristic of an impedance of the acoustic transducer; and an output resistor connected in series with the acoustic transducer is virtually generated by the voltage feedback circuit and the current feedback circuit, and the output resistor has a value greater than a resistance value of the acoustic transducer.

### BRIEF DESCRIPTION OF DRAWINGS

The present disclosure will be described in detail based on the following without being limited thereto.

FIG. 1 is a block diagram showing a configuration example of an acoustic system 1 according to a first embodiment;

FIG. 2 is a circuit diagram showing an equivalent circuit of the acoustic system 1;

FIG. 3 is a graph showing a frequency characteristic of a voltage at a first node N1 of the acoustic system 1;

FIG. 4 is a diagram illustrating an output impedance Zo of a power amplifying device 10;

FIG. 5 is a circuit diagram showing a circuit example of the power amplifying device 10;

FIG. 6 is a circuit diagram showing a circuit example for examining an open output voltage V2;

FIG. 7 is a circuit diagram showing an example of the power amplifying device 10;

FIG. 8 is a circuit diagram showing a configuration example of the acoustic system 1;

FIG. 9 is a circuit diagram showing an example of values of respective elements of the acoustic system 1 shown in FIG. 8;

FIG. 10 is a circuit diagram showing a configuration example of the acoustic system 1 according to a second embodiment;

FIG. 11 is a circuit diagram showing a configuration example of the acoustic system 1 according to a third embodiment; and

FIG. 12 is a graph showing a frequency characteristic of a distortion rate.

### DETAILED DESCRIPTION

### 1. First Embodiment

FIG. 1 is a block diagram showing a configuration example of an acoustic system 1 according to a first embodiment. The acoustic system 1 includes a power amplifying device 10 and a speaker 20. The power amplifying device 10 amplifies an input sound signal Vin to generate an output sound signal Vout. The power amplifying device 10 outputs the output sound signal Vout to the speaker 20. The speaker 20 is an example of an acoustic transducer that converts the output sound signal Vout into sound. The speaker 20 is a dynamic speaker including a voice coil. The speaker 20 includes a speaker unit and an enclosure that accommodates the speaker unit. The speaker 20 is connected to the power amplifying device 10 via a first node N1.

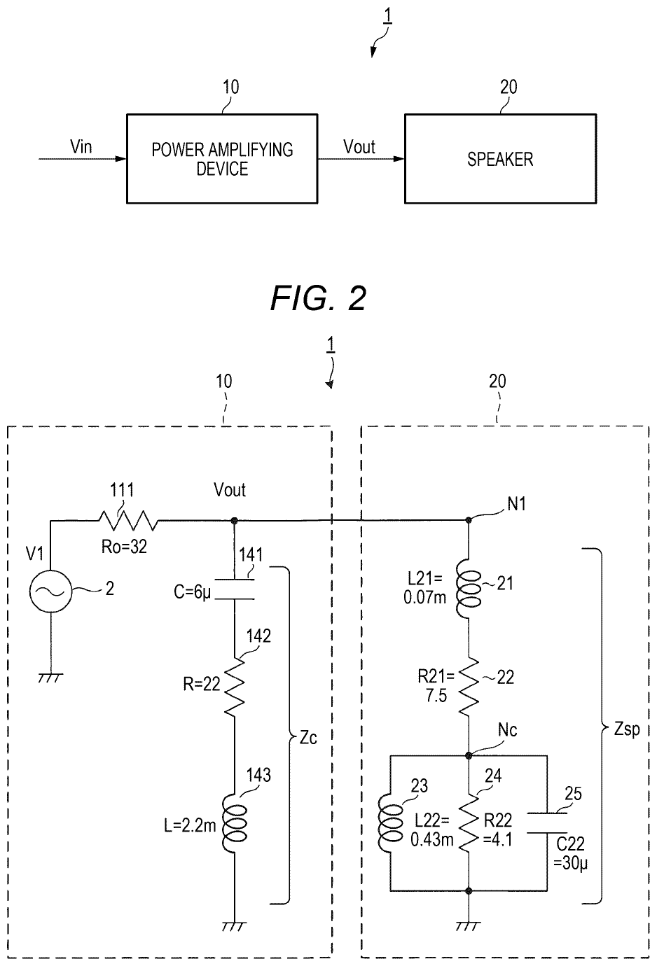

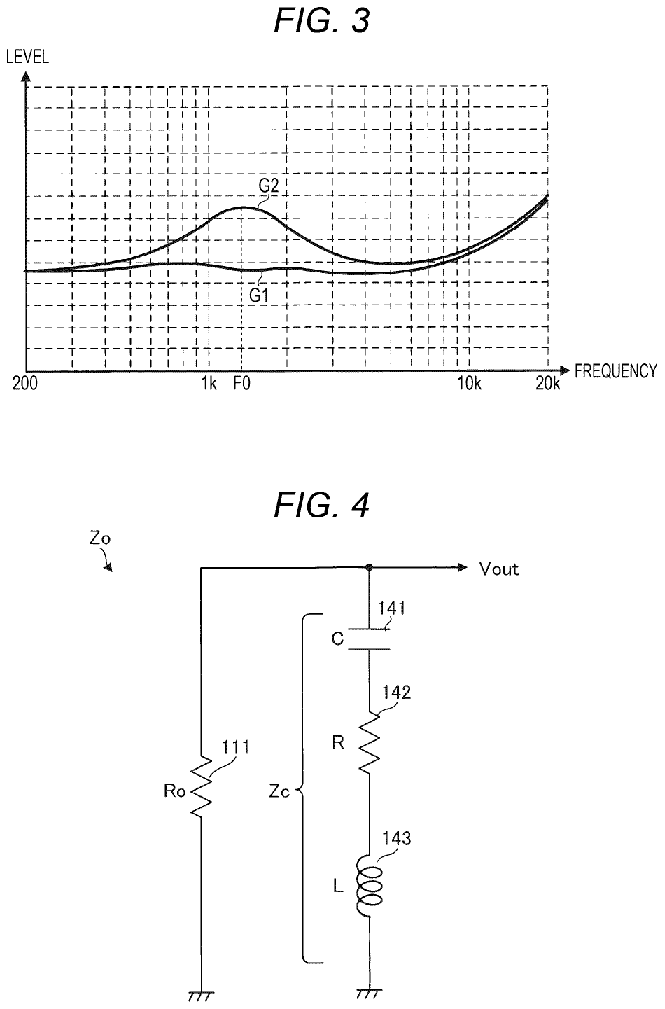

FIG. 2 is a circuit diagram showing an equivalent circuit to be implemented by the acoustic system 1. As shown in FIG. 2, the equivalent circuit of the power amplifying device 10 includes a voltage source 2, an output resistor 111, and an impedance Zc for compensation. One terminal of the output resistor 111 is connected to the voltage source 2. The other terminal of the output resistor 111 is connected to the impedance Zc for compensation. The impedance Zc for compensation is a circuit in which a first capacitor 141, a first resistor 142, and a first coil (inductor) 143 are connected in series. The voltage source 2 is an equivalent circuit corresponding to an amplifier to be described later. An output impedance of the voltage source 2 is zero. An output voltage V1 output from the voltage source 2 is a voltage obtained by amplifying the input sound signal Vin and is proportional to the input sound signal Vin. A resistance value of the output resistor 111 is Ro, and is, for example, 32Ω. A capacitance value of the first capacitor 141 is C, and is, for example, 6 μF. An inductance value of the first coil 143 is L, for example, and is, 2.2 mH.

Here, the output sound signal Vout of the equivalent circuit of FIG. 2 when the speaker 20 is not connected, that is, an open output voltage V2 of the power amplifying device 10 viewed from the speaker 20 is given by the following Formula 1.

$$V 2 = V 1 \times ( Zc / ( Ro + Z c ) ) \qquad Formula 1$$

An impedance Zsp is an impedance of the speaker 20. An equivalent circuit of the speaker 20 includes a coil 21, a resistor 22, a coil 23, a resistor 24, and a capacitor 25. One terminal of the coil 21 is supplied with the output sound signal Vout from the power amplifying device 10 via the first node N1. The other terminal of the coil 21 is connected to one terminal of the resistor 22. The other terminal of the resistor 22 is connected to an intermediate node Nc. The coil 23, the resistor 24, and the capacitor 25 are connected in parallel between the intermediate node Nc and ground. An inductance value of the coil 21 is L21, and is, for example, 0.07 mH. A resistance value of the resistor 24 is R21, and is, for example, 7.5Ω. An inductance value of the coil 23 is L22, and is, for example, 0.43 mH. A resistance value of the resistor 24 is R22, and is, for example, 4.1Ω. A capacitance value of the capacitor 25 is C22, and is, for example, 30 μF.

An inductance represented by the coil 21 is mainly an inductance component of the voice coil of the speaker unit. A resistance represented by the resistor 22 is mainly a resistance component of the voice coil. The coil 23, the resistor 24, and the capacitor 25 are a motional impedance of the speaker 20. The motional impedance is determined according to a structure of the speaker unit and a structure of the enclosure.

Due to the motional impedance, resonance occurs at a low frequency. The resonance frequency is a low-frequency resonance frequency F0 of the speaker 20. FIG. 3 is a graph illustrating the low-frequency resonance frequency F0. A curve G1 in FIG. 3 represents a frequency characteristic of a voltage at the first node N1 of the acoustic system 1, and a frequency characteristic of the motional impedance is flatly compensated by the impedance Zc for compensation connected in parallel. Meanwhile, a curve G2 indicates a frequency characteristic of the voltage at the first node N1 when the impedance Zc for compensation is removed from the acoustic system 1. As in the example, a resonance frequency and a Q value of the impedance Zc for compensation are adjusted to substantially coincide with a resonance frequency and a Q value of the motional impedance.

FIG. 4 is a diagram illustrating an output impedance Zo of the power amplifying device 10. As shown in FIG. 4, the output impedance Zo of the equivalent circuit of FIG. 2 is an impedance of a circuit in which the output resistor 111 and the impedance Zc for compensation are connected in parallel. The output impedance Zo is given by the following Formula 2.

$$Zo = Ro // Zc = Ro \cdot Zc / ( Ro + Zc ) \qquad Formula 2$$

where “//” represents an arithmetic formula of the parallel impedance.

According to Thevenin's law, when, as viewed from the speaker 20, the open output voltage V2 of the equivalent circuit represented by Formula 1 and an open output voltage of a certain circuit coincide with each other and the output impedance of the equivalent circuit represented by Formula 2 and an output impedance of the certain circuit coincide with each other, the certain circuit operates electrically equivalent to the equivalent circuit of FIG. 2. In the present embodiment, a specific example of a circuit of the power amplifying device 10 will be described below using Thevenin's law.

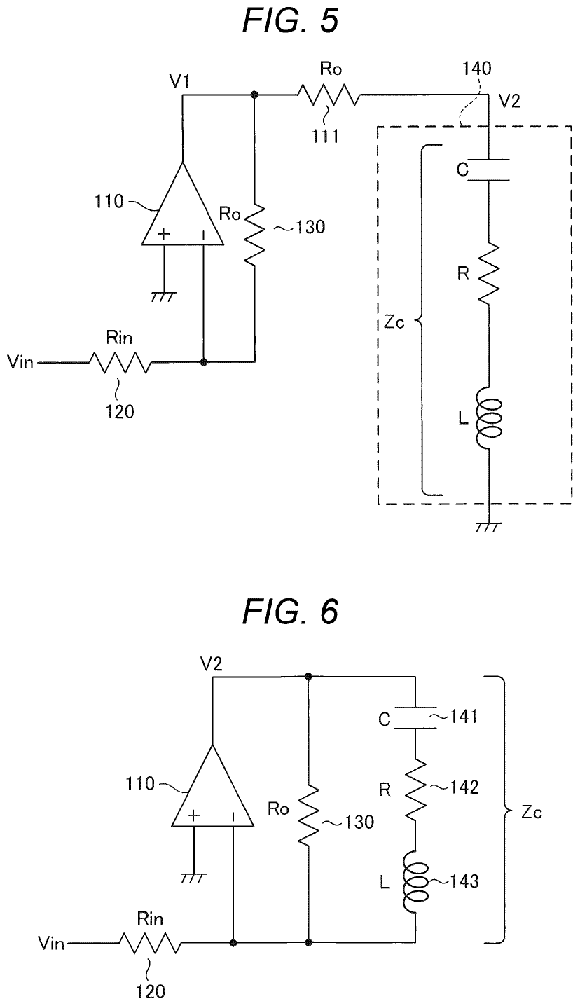

First, a circuit of a power amplifying device that outputs the open output voltage V2 shown in Formula 1 is assumed. FIG. 5 is a circuit example when the speaker 20 is removed from the equivalent circuit of FIG. 2. In FIG. 5, the power amplifying device 10 includes a first amplifier 110, an input resistor 120, a voltage feedback resistor 130, the output resistor 111, and a compensation circuit 140. The first amplifier 110 is a differential amplifier that amplifies a voltage difference between a positive input terminal and a negative input terminal and outputs a voltage proportional to the voltage difference from an output terminal. In the circuit of FIG. 5, an impedance of the input resistor 120 is Rin. An impedance of the output resistor 111 and an impedance of the voltage feedback resistor 130 are both Ro. An impedance of the compensation circuit 140 is Zc.

The input sound signal Vin is supplied to one terminal of the input resistor 120. The negative input terminal of the first amplifier 110 is connected to the other terminal of the input resistor 120. The voltage feedback resistor 130 is provided between the output terminal and the negative input terminal of the first amplifier 110. One terminal of the output resistor 111 is connected to the output terminal of the first amplifier 110. The other terminal of the output resistor 111 is connected to the compensation circuit 140. The compensation circuit 140 is configured by connecting a first capacitor 141, a first resistor 142, and a first coil 143 in series.

In the power amplifying device 10 of FIG. 5, the first amplifier 110 is a voltage source whose output impedance is substantially zero. The output impedance Zo of the power amplifying device 10 is the output impedance Zo shown in FIG. 4.

In the power amplifying device 10 of FIG. 5, the output voltage V1 output from the first amplifier 110 is given by Formula 3 shown below.

$$V 1 = Vin \times Ro / Rin \qquad Formula 3$$

Formula 4 representing the open output voltage V2 is derived from Formula 3 and Formula 1.

$$V 2 = ( Vin \times Ro / Rin ) \times ( Zc / ( Ro + Z c ) ) = Vin \times Ro \times Zc / ( Rin \times ( R o + Z c ) ) \qquad Formula 4$$

Here, a circuit of FIG. 6 having the same open output voltage V2 is assumed. A transfer characteristic of the circuit is given by Formula 5 shown below.

$$Vout = Vin \times ( Ro // Zc ) / Rin = Vin \times Ro \times Zc // ( ( Rin \times ( R o + Z c ) ) \qquad Formula 5$$

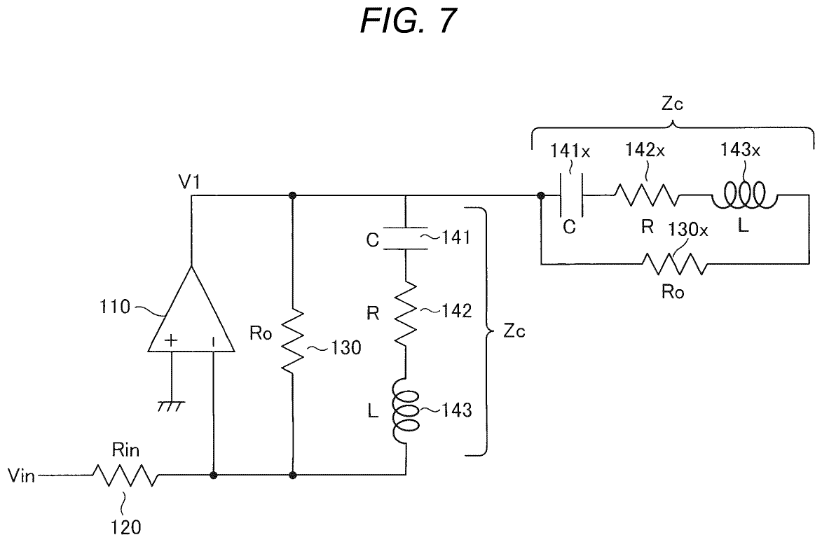

That is, an open output voltage of the assumed circuit of FIG. 6 is the same as the open output voltage V2 of the power amplifying device 10 of FIG. 5. On the other hand, an output impedance of the assumed circuit of FIG. 6 is zero and is not the same as the output impedance of the power amplifying device 10 of FIG. 5. When an impedance Ro//Zc is added to an output of the circuit of FIG. 6, the same output impedance is obtained. FIG. 7 is a circuit obtained by adding the impedance Ro//Zc to the output of the circuit of FIG. 6, and is equivalent to the circuit of FIG. 2.

In the assumed circuit of FIG. 7, the impedance Ro//Zc is connected to the output terminal of the first amplifier 110.

The speaker 20 has so-called current magnetostriction. The current magnetostriction occurs because the impedance Zsp of the speaker 20 includes a nonlinear element. For example, a force generated in the voice coil is determined by a product of an effective magnetic flux density, a length of the voice coil, and a current flowing through the voice coil. That is, in order to accurately perform electroacoustic conversion in the speaker 20, the effective magnetic flux density needs to be uniform regardless of a position of the voice coil. However, in the actual speaker 20, the effective magnetic flux density tends to be non-uniform as the amplitude increases.

That is, the impedance Zsp fluctuates under an influence of the current magnetostriction. A fluctuation component of the impedance Zsp is represented by ΔZsp. When the speaker 20 is driven at a constant voltage, current magnetostriction of ΔZsp/Zsp occurs. Since the speaker 20 of the present embodiment employs a dynamic speaker unit, and a driving force of a cone which is a diaphragm is proportional to the current. Accordingly, the current magnetostriction is converted into sound.

In a case where the speaker 20 is driven using the power amplifying device 10 having an output impedance that is n times a nominal impedance of the speaker unit, a current fluctuation is ΔZsp/(Zsp+n×Zsp) as compared with a case where the speaker 20 is driven using a circuit having an output impedance of the nominal impedance. As a result, the current magnetostriction is 1/(n+1) as compared with that under constant voltage driving. The nominal impedance of the speaker unit is 8Ω, for example.

Therefore, in order to reduce the current magnetostriction, it is preferable to increase a resistance component of the output impedance. However, when the resistance component is implemented by a physical resistor element, a large power loss is generated due to the resistor element.

Therefore, in the present embodiment, the impedance Ro//Zc of FIG. 7 is virtually generated by negatively feeding back the current flowing through the speaker 20, and the frequency characteristic is flattened while reducing the current magnetostriction without increasing the power loss.

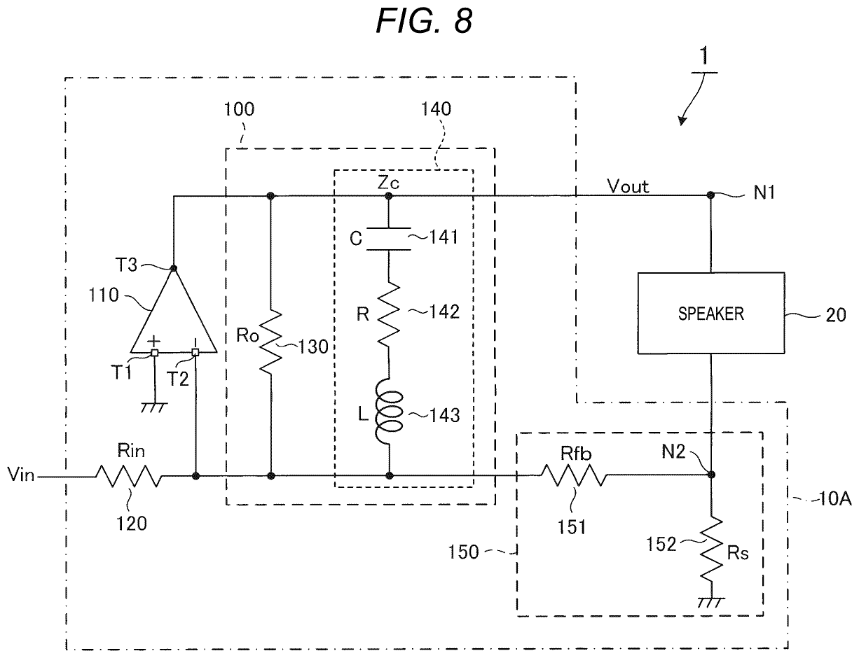

FIG. 8 is a circuit diagram showing a configuration example of the acoustic system 1 in which the impedance Ro//Zc of the output is virtually generated using current feedback in the assumed circuit of FIG. 7. The acoustic system 1 includes a power amplifying device 10A and the speaker 20. That is, a circuit of the power amplifying device 10A is equivalent to the circuit of FIG. 2. The power amplifying device 10A includes the first amplifier 110, the input resistor 120, a voltage feedback circuit 100, and a current feedback circuit 150.

The first amplifier 110 includes a first positive input terminal T1, a first negative input terminal T2, and a first output terminal T3. The input resistor 120 is connected to the first negative input terminal T2. The input sound signal Vin is input to the first negative input terminal T2 via the input resistor 120.

The voltage feedback circuit 100 negatively feeds back the output sound signal Vout to an input of the first amplifier 110. The voltage feedback circuit 100 includes the voltage feedback resistor 130 and the compensation circuit 140 connected in parallel with the voltage feedback resistor 130. The voltage feedback resistor 130 is connected between the first negative input terminal T2 and the first output terminal T3. The compensation circuit 140 is connected between the first negative input terminal T2 and the first output terminal T3. In the compensation circuit 140, the first capacitor 141, the first resistor 142, and the first coil (inductor) 143 are connected in series. A connection order of the first capacitor 141, the first resistor 142, and the first coil 143 is freely set.

The current feedback circuit 150 includes a current feedback resistor 151 and a current detection resistor 152. The current feedback resistor 151 is connected between a second node N2 and the first negative input terminal T2. The speaker 20 and the current detection resistor 152 are connected to the second node N2. The current detection resistor 152 is used to detect a current flowing through the speaker. The current detection resistor 152 is connected between the speaker 20 and the ground. A resistance value of the current feedback resistor 151 is Rfb. A resistance value of the current detection resistor 152 is Rs.

An output impedance Zout virtually generated in the power amplifying device 10A by the current feedback based on the resistor Rfb is given by the following Formula 6.

$$Zout = Rs \times ( Ro // Zc ) / Rfb = ( Rs / Rfb ) \times Ro \times Zc / ( Ro + Z c ) ) \qquad Formula 6$$

Here, when the resistance value of the current feedback resistor 151 and the resistance value of the current detection resistor 152 are set such that Rs/Rfb=1, Formula 6 becomes Formula 7 shown below.

$$Zout = R o \times Zc / ( Ro + Z c ) \qquad Formula 7$$

By comparing Formula 2 and Formula 7, it is understood that the output impedance Zo of the power amplifying device 10 and the output impedance Zout of the power amplifying device 10A are the same. A voltage of the first node N1 when the speaker 20 is disconnected from the first node N1 is Vout shown in Formula 5. Thus, the acoustic system 1 of FIG. 8 is equivalent to the equivalent circuit of the acoustic system 1 of FIG. 2 (FIG. 5) and the assumed circuit of FIG. 7 from a viewpoint of Thevenin's law. That is, the output of the power amplifying device 10A of the acoustic system 1 of FIG. 8 is regarded as the virtual resistor 111 connected in series to the speaker 20 and the virtual impedance Zc connected in parallel with the speaker 20, similarly to the equivalent circuit of FIG. 2.

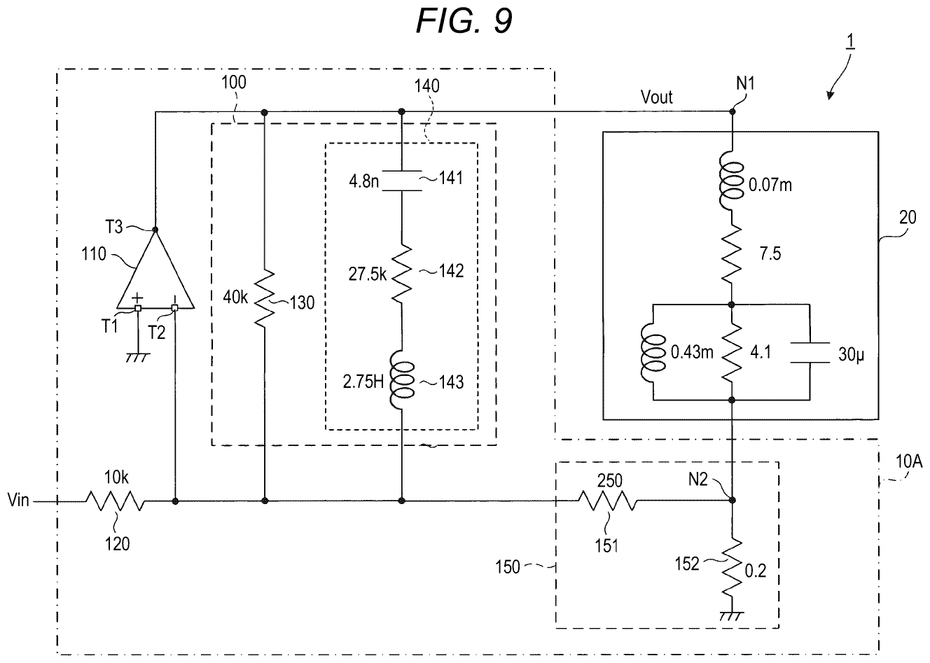

FIG. 9 is a circuit diagram showing an example of values of elements of the acoustic system 1 of FIG. 8. When the impedance of the compensation circuit 140 is matched with the impedance of the speaker 20 as shown in FIG. 5, the first amplifier 110 is too small for the voltage feedback circuit 100. Therefore, in the acoustic system 1 of FIG. 9, the impedance of the voltage feedback circuit 100 and the impedance of the current feedback resistor 151 are designed to be 1250 times that in the case of FIG. 5 with the same transfer characteristic as that of the acoustic system 1 of FIG. 8.

As described above, according to the present embodiment, the power amplifying device 10A that generates the output sound signal Vout by power-amplifying the input sound signal Vin includes the first amplifier 110 that outputs the output sound signal Vout to the speaker 20 that converts the output sound signal Vout into sound; the voltage feedback circuit 100 that negatively feeds back a voltage of the output sound signal Vout to an input of the first amplifier 110; and the current feedback circuit 150 that negatively feeds back a voltage corresponding to the current flowing through the speaker 20 to the input of the first amplifier 110. Further, the voltage feedback circuit 100 includes the voltage feedback resistor 130 and the compensation circuit 140 connected in parallel with the voltage feedback resistor 130.

As described above, the output of the power amplifying device 10A of FIG. 8 can be virtually considered as that the same impedance Zc as the impedance Zc for compensation in the equivalent circuit of FIG. 2 is connected in parallel with the speaker 20, and the curve G1 of FIG. 3 is realized by the flat frequency characteristic of the impedance of the parallel circuit. Accordingly, the frequency characteristic of the impedance of the parallel circuit is flat as compared with the frequency characteristic G2 of the impedance of the speaker 20. Accordingly, the power amplifying device 10A can drive the speaker 20 with a voltage having a flat frequency characteristic as compared with a case where the impedance Zc of FIG. 2 is eliminated and the speaker 20 is driven only by the output resistor 111.

Further, as described above, as the output of the power amplifying device 10A, a resistor the same as the output resistor 111 in FIG. 2 is virtually connected in series with the speaker 20. Here, the circuit is designed such that the resistance value Ro of the output resistor 111 is sufficiently larger than a sum of the resistance values R21 and R22 of the speaker 20. Ro illustrated in FIG. 2 is 32Ω, and the sum of R21 and R22 is 11.6Ω. In this case, the current magnetostriction is reduced to about ¼.

That is, the power amplifying device 10A virtually drives a series circuit, in which the parallel circuit of the impedance Zsp of the speaker 20 and the virtual impedance Zc for compensation is connected with the virtual output resistor 111 in series, by the output voltage V1 proportional to the input sound signal Vin. As a result, the voltage of the first node N1 when the speaker 20 is connected thereto is a voltage having a flat frequency characteristic and obtained by dividing the output voltage V1 by the output resistor 111 and the impedance of the parallel circuit. On the other hand, the voltage of the first node N1 when the speaker 20 is not connected thereto is a voltage (open output voltage V2) obtained by dividing the output voltage V1 by the output resistor 111 and the impedance Zc for compensation.

Further, the current feedback circuit 150 negatively feeds back the voltage of the current detection resistor 152 connected between the speaker 20 and the ground to the first amplifier 110 by the current feedback resistor 151, which is connected between the second node N2 to which the speaker 20 and the current detection resistor 152 are connected and the first negative input terminal T2. That is, the current flowing through the speaker 20 is negatively fed back to the first amplifier 110 via the current feedback resistor 151.

Further, the compensation circuit 140 includes the first capacitor 141, the first coil (inductor) 143, and the first resistor 142 which are connected in series in any order between the first negative input terminal T2 and the first output terminal T3. The first coil may be a simulated inductor. At the low-frequency resonance frequency F0 of the speaker 20, a value of the motional impedance of the speaker 20 increases. Due to the current feedback, a compensation impedance having the same frequency characteristic as that of the compensation circuit 140 is virtually generated in parallel with the speaker 20 at the output of the power amplifying device 10A, and an influence of the motional impedance of the speaker 20 is cancelled.

### 2. Second Embodiment

The compensation circuit 140 of the power amplifying device 10A according to the first embodiment is configured by connecting the first capacitor 141, the first resistor 142, and the first coil 143 in series. Both terminals of the first coil 143 are floated. In contrast, the power amplifying device 10A of a second embodiment is different from the power amplifying device 10A of the first embodiment in that a coil having one terminal grounded is used.

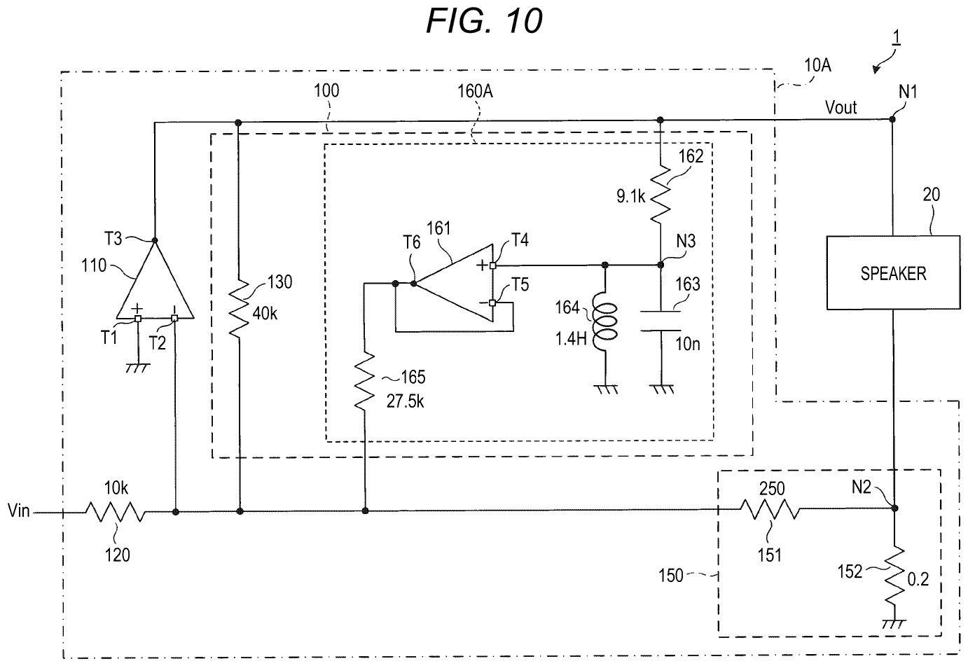

FIG. 10 shows a configuration example of the acoustic system 1 according to the second embodiment. The acoustic system 1 according to the second embodiment has the same configuration as the acoustic system 1 according to the first embodiment of FIG. 9 except that a compensation circuit 160A having the same characteristic as the compensation circuit 140 is used instead of the compensation circuit 140 of the power amplifying device 10A. Hereinafter, the compensation circuit 160A will be described.

The compensation circuit 160A of FIG. 10 includes a second amplifier 161, a second resistor 162, a second capacitor 163, a second coil 164, and a third resistor 165. The second amplifier 161 includes a second positive input terminal T4, a second negative input terminal T5, and a second output terminal T6. The second output terminal T6 is connected to the second negative input terminal T5. The second amplifier 161 functions as a voltage follower.

The second resistor 162 is provided between the first output terminal T3 of the first amplifier 110 and the second positive input terminal T4. The resistance value of the second resistor 162 is, for example, 9.1 kΩ. The second capacitor 163 is provided between the second positive input terminal T4 and the ground. Each of the second resistor 162 and the second capacitor 163 is connected to a third node N3. A capacitance value of the second capacitor 163 is, for example, 10 nF. The second coil 164 is provided between the second positive input terminal T4 and the ground. An inductance value of the second coil 164 is, for example, 1.4 H. The third resistor 165 is provided between the second output terminal T6 and the first negative input terminal T2 of the first amplifier 110. A resistance value of the third resistor 165 is, for example, 27.5 kΩ.

### 3. Third Embodiment

The compensation circuit 160A according to the second embodiment includes the second coil 164. In contrast, the acoustic system 1 according to a third embodiment is different in that the second coil 164 is a simulated inductor. The corresponding simulated inductor as the grounded second coil 164 is simpler than the floating first coil 143 of the first embodiment.

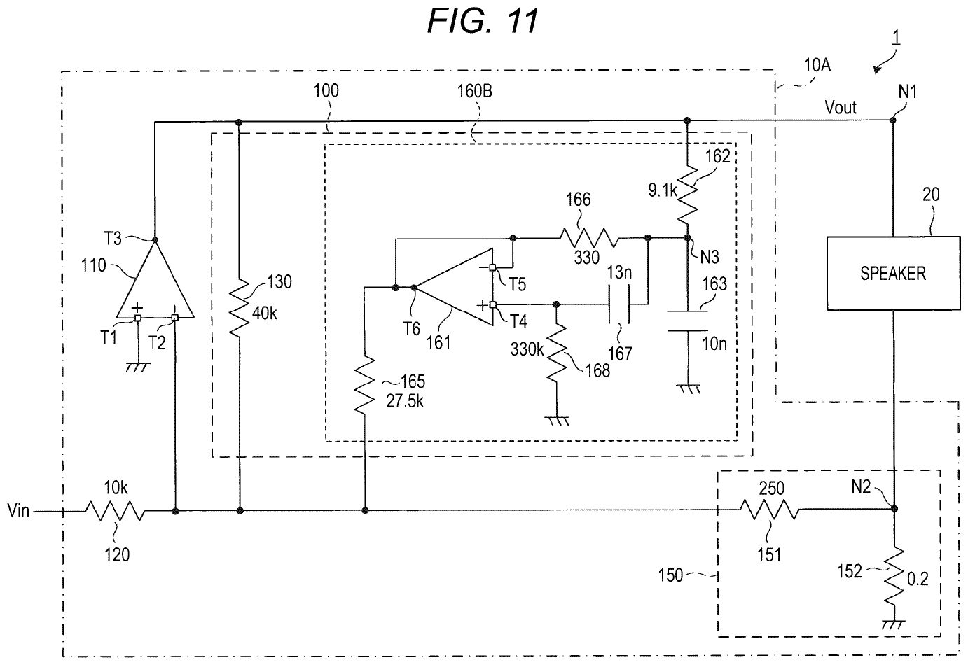

FIG. 11 shows a configuration example of the acoustic system 1 according to the third embodiment. The acoustic system 1 according to the third embodiment has the same configuration as the acoustic system 1 according to the second embodiment of FIG. 10 except that a compensation circuit 160B is used instead of the compensation circuit 160A of the power amplifying device 10A. Hereinafter, the compensation circuit 160B will be described.

The compensation circuit 160B of FIG. 11 is connected between the first negative input terminal T2 and the first output terminal T3 of the first amplifier 110. The compensation circuit 160B includes a simulated inductor using the second amplifier 161.

The compensation circuit 160B includes the second amplifier 161, the second resistor 162, the second capacitor 163, the third resistor 165, a fourth resistor 166, a third capacitor 167, and a fifth resistor 168. The second resistor 162 is provided between the first output terminal T3 of the first amplifier 110 and the third node N3. The third resistor 165 is provided between the second output terminal T6 and the first negative input terminal T2 of the first amplifier 110. The second capacitor 163 is provided between the third node N3 and the ground. The third capacitor 167 is provided between the third node N3 and the second positive input terminal T4. A capacitance value of the third capacitor 167 is, for example, 13 nF. The fourth resistor 166 is provided between the third node N3 and the second negative input terminal T5. A resistance value of the fourth resistor 166 is, for example, 330Ω. The fifth resistor 168 is provided between the second positive input terminal T4 and the ground.

According to the compensation circuit 160B described above, the second amplifier 161, the fourth resistor 166, the third capacitor 167, and the fifth resistor 168 constitute a simulated inductor. An inductance value of the simulated inductor is equal to the inductance value of the second coil 164 in FIG. 10. The compensation circuit 160B can be reduced in a circuit size as compared with the compensation circuit 160A since the second coil 164 having a large size is replaced with the simulated inductor.

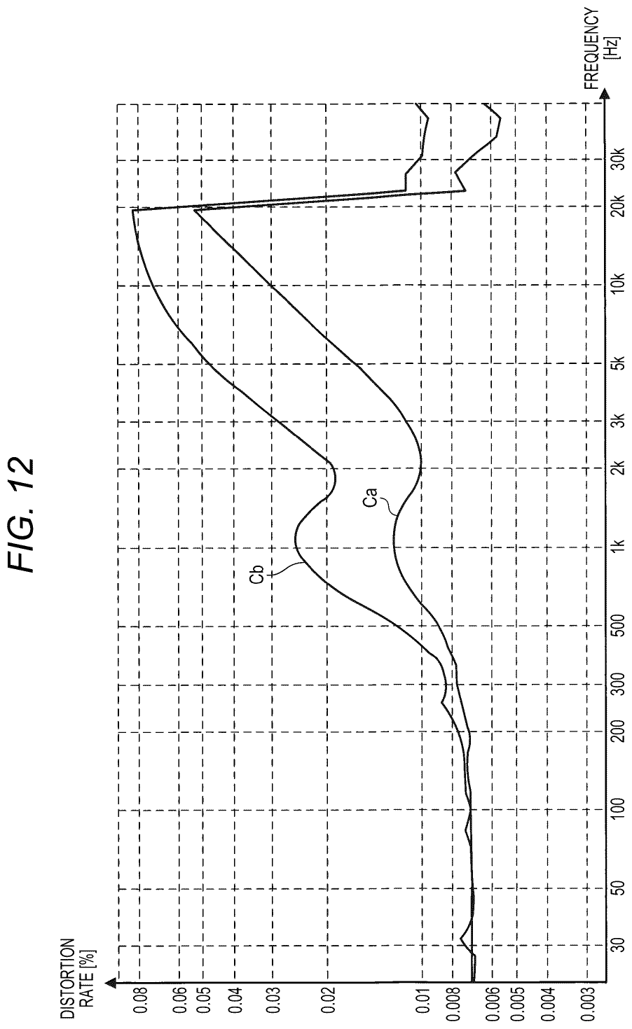

FIG. 12 is a graph showing a frequency characteristic of a distortion rate. In FIG. 12, a curve Ca indicates a distortion rate of the current flowing through the speaker 20 when the speaker 20 is driven by the power amplifying device 10A as shown in FIG. 11, and a curve Cb indicates a distortion rate of the current when the speaker 20 is driven by a power amplifying device of constant voltage drive (obtained by removing the current feedback resistor 151 and the compensation circuit 160B from FIG. 11). When the curve Ca and the curve Cb are compared, the distortion rate of the power amplifying device 10A is improved by about 6 dB to 10 dB in a frequency band of 1 kHz or more.

### 4. Modification

The present disclosure is not limited to the above-described embodiments, and various modifications described below are possible. Further, each embodiment and each modification may be appropriately combined.

### (1) Modification 1

In each of the above-described embodiments, the power amplifying device 10A is provided outside the speaker 20, but the present disclosure is not limited thereto. For example, the speaker 20 may be a powered speaker in which the power amplifying device 10A is provided inside the speaker 20. The compensation circuit 140, 160A, or 160B is designed according to the impedance Zsp of a specific speaker 20. Therefore, the power amplifying device 10A is not suitable for a speaker having an impedance different from that of the speaker. In the powered speaker, the power amplifying device 10A suitable for the specific speaker 20 can be incorporated into the enclosure.

### (2) Modification 2

The first amplifier 110 in each of FIGS. 5 to 11 is designed as an inverting amplifier that inputs the input voltage Vin to the negative input terminal, but can be easily redesigned as a non-inverting amplifier that inputs the input voltage Vin to the positive input terminal.

### (3) Modification 3

In each of the above-described embodiments, the speaker 20 is described as an example of the acoustic transducer. The acoustic transducer is a device that converts electric energy into sound. In the present disclosure, the acoustic transducer converts the output sound signal Vout into sound. That is, the present disclosure is not limited to the speaker. The acoustic transducer may be a compression driver or an earphone driver. The acoustic transducer also includes an acoustic transducer that vibrates a wall or the like with electric energy.

### (4) Modification 4

In each of the above-described embodiments, the impedance Zc of the compensation circuits 140, 160A or 160B is designed such that the frequency characteristic of the impedance of the parallel circuit is flat according to the impedance Zsp of the speaker 20. However, the frequency characteristic of the impedance of the parallel circuit does not need to be completely flat, and may be close to flat as compared with the frequency characteristic of the impedance of the speaker 20 alone.

What is claimed is:

1. A power amplifying device configured to generate an output sound signal by power amplifying an input sound signal, the power amplifying device comprising:
an amplifier circuit configured to amplify the input sound signal and output an amplified signal as the output sound signal to an acoustic transducer configured to convert the output sound signal into sound;
a voltage feedback circuit configured to negatively feed back a voltage of the output sound signal to an input of the amplifier circuit; and
a current feedback circuit configured to negatively feed back a current flowing through the acoustic transducer to the input of the amplifier circuit, wherein
the voltage feedback circuit comprises a voltage feedback resistor and a compensation circuit connected in parallel with the voltage feedback resistor,
a compensation impedance connected in parallel with the acoustic transducer is virtually generated by the voltage feedback circuit and the current feedback circuit, and an impedance of a parallel circuit in which the acoustic transducer and the compensation impedance are connected in parallel is flat as compared with a frequency characteristic of an impedance of the acoustic transducer, and
an output resistor connected in series with the acoustic transducer is virtually generated by the voltage feedback circuit and the current feedback circuit, and the output resistor has a value greater than a resistance value of the acoustic transducer.

2. The power amplifying device according to claim 1, wherein
the power amplifying device is configured to virtually drive a series circuit, in which the impedance of the parallel circuit and the output resistor are connected in series, by an output voltage proportional to the input sound signal.

3. The power amplifying device according to claim 2, wherein
the acoustic transducer is connected to an output of the amplifier circuit via a first node, and
a voltage of the first node when the acoustic transducer is not connected to the first node is a voltage obtained by dividing the output voltage by the output resistor and the compensation impedance.

4. The power amplifying device according to claim 1, wherein
the amplifier circuit is a first amplifier comprising a first positive input terminal, a first negative input terminal, and a first output terminal, and
the current feedback circuit comprises:
a current detection resistor configured to detect current, and connected between the acoustic transducer and ground; and
a current feedback resistor connected between a second node, to which the acoustic transducer and the current detection resistor are connected, and the first negative input terminal.

5. The power amplifying device according to claim 1, wherein
the amplifier circuit is a first amplifier comprising a first positive input terminal, a first negative input terminal, and a first output terminal,
the voltage feedback resistor is connected between the first negative input terminal and the first output terminal, and
the compensation circuit comprises a first capacitor, a first inductor, and a first resistor which are connected in series in any order between the first negative input terminal and the first output terminal.

6. The power amplifying device according to claim 1, wherein
the amplifier circuit is a first amplifier comprising a first positive input terminal, a first negative input terminal, and a first output terminal,
the voltage feedback resistor is connected between the first negative input terminal and the first output terminal, and
the compensation circuit comprises:
a second amplifier comprising a second positive input terminal, a second negative input terminal, and a second output terminal connected with the second negative input terminal;
a second resistor provided between the first output terminal and the second positive input terminal;
a second capacitor provided between the second positive input terminal and ground;
a second coil provided between the second positive input terminal and the ground; and
a third resistor provided between the second output terminal and the first negative input terminal.

7. The power amplifying device according to claim 1, wherein
the amplifier circuit is a first amplifier comprising a first positive input terminal, a first negative input terminal, and a first output terminal,
the voltage feedback resistor is connected between the first negative input terminal and the first output terminal, and
the compensation circuit is connected between the first negative input terminal and the first output terminal and comprises a simulated inductor using a second amplifier.

8. The power amplifying device according to claim 7, wherein
the second amplifier comprises a second positive input terminal, a second negative input terminal, and a second output terminal, and
the compensation circuit comprises:
a second resistor provided between the first output terminal and a third node,
a third resistor provided between the second output terminal and the first negative input terminal,
a second capacitor provided between the third node and ground,
a third capacitor provided between the third node and the second positive input terminal,
a fourth resistor provided between the third node and the second negative input terminal, and
a fifth resistor provided between the second positive input terminal and the ground.
